(19) United States
(12) Patent Application Publication
(10) Pub. No.: US 2016/0254280 A1
(43) Pub. Date: Sep. 1, 2016

(54) THIN-FILM TRANSISTOR AND METHOD OF MANUFACTURING THE SAME

(71) Applicant: JOLED INC., Tokyo (JP)

(72) Inventors: Mami NONOGUCHI, Nara (JP); Tomoaki IZUMI, Tokyo (JP); Hiroshi HAYASHI, Tokyo (JP); Yuji KISHIDA, Tokyo (JP)

(73) Assignee: JOLED INC., Tokyo (JP)

(21) Appl. No.: 15/030,081

(22) PCT Filed: Jul. 17, 2014
(86) PCT No.: PCT/JP2014/003813

§ 371 Date: Apr. 18, 2016

(30) Foreign Application Priority Data
Nov. 6, 2013 (JP) 2013-230017

(51) Int. Cl. H01L 27/12; H01L 29/786; H01L 29/66; H01L 29/24

(52) U.S. Cl. CPC H01L 27/1225; H01L 27/127; H01L 29/247; H01L 29/78693; H01L 29/78696; H01L 29/66969; H01L 29/78606; H01L 27/3262

(57) ABSTRACT

A thin-film transistor includes: an oxide semiconductor layer; an insulating layer formed above the oxide semiconductor layer; and a source electrode and a drain electrode which are located at least partially on the insulating layer and are connected to the oxide semiconductor layer via an opening formed in the insulating layer. The thin-film transistor satisfies a relational expression L1≧5.041 exp(5×10⁻¹⁸N), where L1 (μm) is one of protrusion widths of the oxide semiconductor layer in a channel width direction with respect to the source electrode or the drain electrode and N (cm⁻³) is a carrier density of the oxide semiconductor layer.

### TECHNICAL FIELD

The present disclosure relates to a thin-film transistor and a method of manufacturing the thin-film transistor.

### BACKGROUND ART

Thin-film transistors (TFTs) are widely used as switching elements or drive elements in active matrix display apparatuses, such as liquid crystal display apparatuses or organic light-emitting diode (OLED) display apparatuses. Examples of the material for a semiconductor layer of the TFT include amorphous silicon. The semiconductor layer has a channel region in which carrier transfer is controlled by means of a voltage applied to a gate electrode.

The active matrix display apparatuses are required to support higher-definition screens and higher frame rates, as well as to have higher-performance switching and drive TFTs. More effort has been also directed toward research and development to achieve next-generation display apparatuses, which are to be more flexible or more transparent. With this being the situation, an increasing interest in the material for the semiconductor layer of the TFT has a tendency to focus on a material which is transparent and enables a low-temperature film formation on a flexible substrate in addition to having superiority in electrical characteristics over the conventional silicon-based materials. A growing number of experimental application attempts have been made using metal oxides, such as indium (In), gallium (Ga), zinc (Zn), and tin (Sn) in particular, or compounds of these metal oxides.

As an example, Patent Literature (PTL) 1 discloses a thin-film transistor on which an oxide semiconductor film is formed under a predetermined condition.

### CITATION LIST

### Patent Literature

[PTL 1] U.S. Pat. No. 8,389,310 Specification

### SUMMARY OF INVENTION

### Technical Problem

However, with the aforementioned conventional technique, a thin-film transistor having sufficiently stable characteristics cannot be manufactured.

For example, according to the method of manufacturing a thin-film transistor disclosed in PTL 1, an oxide semiconductor film is formed under a predetermined condition to reduce a leakage current. However, the thin-film transistor having a conventional oxide semiconductor exhibits a hump phenomenon remarkably appearing in a region where the current rapidly increases in the transistor characteristics after the application of stress.

To solve the aforementioned problem, the present disclosure provides a thin-film transistor that has more stable characteristics and higher reliability, and a method of manufacturing the thin-film transistor.

### Solution to Problem

To achieve the aforementioned object, a thin-film transistor according to an aspect includes: a gate electrode located above a substrate; a gate insulating film located above the gate electrode; an oxide semiconductor layer opposite to the gate electrode, with the gate insulating film being interposed in between; an insulating layer formed above the oxide semiconductor layer; and a source electrode and a drain electrode which are located at least partially above the insulating layer and are connected to the oxide semiconductor layer via an opening formed in the insulating layer, wherein the thin-film transistor satisfies a relational expression L1≧5.041 exp(5×10⁻¹⁸N), where L1 (μm) is one of protrusion widths of the oxide semiconductor layer in a channel width direction with respect to one of the source electrode and the drain electrode and N (cm⁻³) is a carrier density of the oxide semiconductor layer.

### Advantageous Effects of Invention

According to the present disclosure, a thin-film transistor having superior transistor characteristics can be provided. In particular, it is possible to obtain a thin-film transistor that reduces the hump phenomenon in a subthreshold region, has more stable initial characteristics, reduces time degradation caused by the application of negative voltage to a gate electrode, and has higher reliability.

### BRIEF DESCRIPTION OF DRAWINGS

FIG. 1 is a partially-cutaway perspective view of an organic electroluminescent (EL) display apparatus according to Embodiment.

FIG. 2 is an electric circuit diagram showing a simplified configuration of a pixel circuit included in the organic EL display apparatus according to Embodiment.

FIG. 3 is a schematic cross-sectional view of a thin-film transistor according to Embodiment.

FIG. 4 is a schematic cross-sectional view showing a method of manufacturing the thin-film transistor according to Embodiment.

FIG. 5A is a schematic top view of the thin-film transistor according to Embodiment.

FIG. 5B is a cross-sectional view of the thin-film transistor taken along a line A-A′ of FIG. 5A.

FIG. 5C is a cross-sectional view of the thin-film transistor taken along a line B-B′ of FIG. 5A.

FIG. 6A is a diagram showing a current density distribution of an oxide semiconductor layer of the thin-film transistor when a drain voltage is applied according to Embodiment.

FIG. 6B is a graph showing the relationship between a protrusion width L1 and a current density distribution of the oxide semiconductor layer of the thin-film transistor according to Embodiment.

FIG. 7 is a graph showing the relationship between the protrusion width L1 and the carrier density of the oxide semiconductor layer of the thin-film transistor according to Embodiment.

FIG. 8 is a diagram showing the relationships between the current and the gate voltage and between the carrier mobility and the gate voltage, as a result of a negative bias temperature stress (NBTS) test performed on the thin-film transistor according to Embodiment ((a) to (c)), as well as showing the relationship between the protrusion width and the shift amount of the threshold voltage in the oxide semiconductor layer according to Embodiment ((d)).

### DESCRIPTION OF EMBODIMENTS

### (Underlying Knowledge Forming Basis of the Present Disclosure)

The inventors particularly noted that a phenomenon called “hump” remarkably appears in a region where the current rapidly increases in the transistor characteristics after the application of stress (this region is referred to as the “subthreshold region”). This region corresponds to a low gradation region of a display apparatus, that is, a black display region. The characteristics of this black display region are important for an organic electroluminescent (EL) display in contrast to a liquid crystal display.

The hump phenomenon described here refers to an occurrence of abnormality in the flowing current in I-V characteristics that indicate the switching characteristics of the TFT. In a logarithmic plot of the current flowing in response to the applied voltage, the current usually increases rapidly and thus exhibits one apparent step of the ON/OFF switching characteristics. Hence, this current slope is defined by a single gradient. The hump phenomenon refers to an occurrence of such a current increase in the switching characteristics of the TFT in a staircase pattern over multiple steps.

The hump phenomenon decreases the thresholds of the TFT characteristics and thus interferes with the achievement of clear switching characteristics, thereby leading to degradation in medium- and long-term reliability due to the voltage application. This degradation in reliability is indicated by no switching characteristics exhibited by the TFT or variations in the threshold voltage. The degradation in reliability disables stable driving performance.

The hump phenomenon is assumed to be caused by the following reason. The semiconductor layer of the TFT has tapered edges as a result of machining, causing unevenness in the film thickness. The application of voltage to an electrode laminated on such a semiconductor layer causes unevenness in the electric field. This in turn causes the semiconductor layer to have a region that is not uniform in the current path and thereby forms a sub-TFT different from the main TFT. Hence, the hump phenomenon is assumed to be caused.

### (Summary of Present Disclosure)

A thin-film transistor according to an aspect of the present disclosure includes: a gate electrode located above a substrate; a gate insulating film located above the gate electrode; an oxide semiconductor layer opposite to the gate electrode, with the gate insulating film being interposed in between; an insulating layer formed above the oxide semiconductor layer; and a source electrode and a drain electrode which are located at least partially above the insulating layer and are connected to the oxide semiconductor layer via an opening formed in the insulating layer, wherein the thin-film transistor satisfies a relational expression L1≧5.041 exp(5×10⁻¹⁸N), where L1 (μm) is one of protrusion widths of the oxide semiconductor layer in a channel width direction with respect to one of the source electrode and the drain electrode and N (cm⁻³) is a carrier density of the oxide semiconductor layer.

A thin-film transistor according to another aspect of the present disclosure is a channel protection (top contact) transistor in which a source electrode and a drain electrode are formed above an insulating layer. A protrusion width L1 (μm) of an oxide semiconductor layer and a carrier density N (cm⁻³) of the oxide semiconductor layer satisfy a relational expression L1≧5.041 exp(5×10⁻¹⁸N), where a boundary is represented by L1=5.041 exp(5×10⁻¹⁸N). Note that, from this relational expression, a relational expression of the carrier density can be derived as N≦2×10¹⁷ In (L1)−3.24×10¹⁷.

The satisfaction of the relational expression allows the width of the oxide semiconductor layer to be greater than the width of the source electrode (the drain electrode). Thus, the tapered parts of the edge parts of the oxide semiconductor layer can be located outside the channel region.

With this, the edge parts of the oxide semiconductor layer can be distanced from the channel region, which state can suppress an occurrence of a region having a high current density at the edge parts of the oxide semiconductor layer. Hence, a thin-film transistor having more stable characteristics and higher reliability can be obtained.

Moreover, in a thin-film transistor according to another aspect of the present disclosure, the carrier density N (cm⁻³) of the oxide semiconductor layer may further satisfy a relational expression 1.13×10¹³ cm⁻³≦N≦1.13×10¹⁶ cm^{×3}.

Furthermore, in a thin-film transistor according to another aspect of the present disclosure, the oxide semiconductor layer may comprise a transparent amorphous oxide semiconductor. To be more specific, the oxide semiconductor layer may comprise indium gallium zinc oxide (InGaZnO).

As described, the use of the oxide semiconductor layer comprising, for example, InGaZnO, as the channel layer of the TFT can increase the carrier mobility.

Moreover, an organic EL display apparatus according to another aspect of the present disclosure includes the thin-film transistor according to one of the aspects described above.

Furthermore, a method of manufacturing a thin-film transistor according to another aspect of the present disclosure includes: forming a gate electrode above a substrate; forming a gate insulating film above the gate electrode; forming an oxide semiconductor film above the gate insulating film; forming an oxide semiconductor layer by processing the oxide semiconductor film into a predetermined shape; forming an insulating layer above the oxide semiconductor layer in a manner that causes the oxide semiconductor layer to have an exposed part; and forming a source electrode and a drain electrode above the insulating layer in a manner that causes the source electrode and the drain electrode to be connected to the exposed part of the oxide semiconductor layer, wherein the thin-film transistor satisfies a relational expression L1≧5.041 exp(5×10⁻¹⁸N), where L1 (μm) is one of protrusion widths of the oxide semiconductor layer in a channel width direction with respect to one of the source electrode and the drain electrode and N (cm⁻³) is a carrier density of the oxide semiconductor layer.

With this, the edge parts of the oxide semiconductor layer can be distanced from the channel region, which state can suppress an occurrence of a region having a high current density at the edge parts of the oxide semiconductor layer. Hence, a thin-film transistor having more stable characteristics and higher reliability can be obtained.

Moreover, in the method of manufacturing a thin-film transistor according to another aspect of the present disclosure, the carrier density N (cm⁻³) of the oxide semiconductor layer may further satisfy a relational expression 1.13×10¹³ cm⁻³≦N≦1.13×10¹⁶ cm⁻³.

Furthermore, in the method of manufacturing a thin-film transistor according to another aspect of the present disclosure, the oxide semiconductor film may comprise a transparent amorphous oxide semiconductor.

As described, the use of the oxide semiconductor layer comprising, for example, InGaZnO, as the channel layer of the TFT can increase the carrier mobility.

### Embodiment

Hereinafter, a thin-film transistor, a method of manufacturing the thin-film transistor, and an organic EL display apparatus including the thin-film transistor according to exemplary embodiments are described with reference to the accompanying drawings. It should be noted that each of the exemplary embodiments below describes only a preferred specific example. Therefore, the numerical values, shapes, materials, structural elements, the arrangement and connection of the structural elements, processes, the processing order of the steps, and so forth described in the following exemplary embodiments are merely examples, and are not intended to limit the present invention. Thus, among the structural elements in the following exemplary embodiments, structural elements that are not recited in any one of the independent claims indicating top concepts according to the present invention are described as arbitrary structural elements.

Note that each of the figures are only schematic diagrams and are not necessarily precise representations. Note also that, in all the figures, the same reference numerals are given to the substantially same structural elements and redundant description thereof shall be omitted or simplified.

### [Organic EL Display Apparatus]

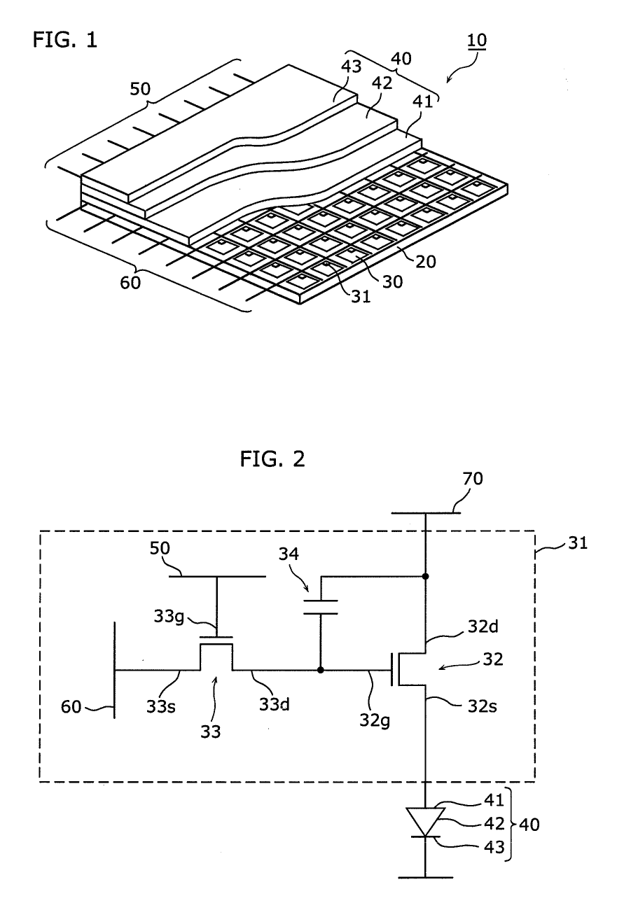

First, a configuration of an organic EL display apparatus 10 according to Embodiment is described with reference to FIG. 1. FIG. 1 is a partially-cutaway perspective view of the organic EL display apparatus according to Embodiment.

As shown in FIG. 1, the organic EL display apparatus 10 is formed by laminating the following: a TFT substrate (a TFT array substrate) 20 on which a plurality of thin-film transistors are arranged; and an organic EL element (a light emitting unit) 40 having an anode 41 as a lower electrode, an EL layer 42 as a light emitting layer comprising an organic material, and a cathode 43 as a transparent upper electrode.

A plurality of pixels 30 are arranged in a matrix on the TFT substrate 20. Each of the pixels 30 is provided with a pixel circuit 31.

The organic EL element 40 is formed for each of the pixels 30. The light emission of the organic EL element 40 is controlled by the pixel circuit 31 of the corresponding pixel 30. The organic EL element 40 is formed on an interlayer insulating film (a flattening film) formed in a manner that the thin-film transistors are covered.

Moreover, the organic EL element 40 has a configuration in which the EL layer 42 is arranged between the anode 41 and the cathode 43. Furthermore, a hole transport layer is formed and laminated between the anode 41 and the EL layer 42, and an electron transport layer is formed and laminated between the EL layer 42 and the cathode 43. It should be noted that a different charge function layer may be formed between the anode 41 and the cathode 43.

Drive of each of the pixels 30 is controlled by the corresponding pixel circuit 31. On the TFT substrate 20, the following are formed: a plurality of gate lines (scanning lines) 50 arranged along the direction of rows of the pixels 30; a plurality of source lines (signal lines) 60 arranged along the direction of columns of the pixels 30 to cross the gate lines 50; and a plurality of power source lines (not illustrated in FIG. 1) arranged in parallel with the source lines 60. The pixels 30 are partitioned by, for example, the gate lines 50 and the source lines 60 that are orthogonal to each other.

The gate line 50 is connected to, for each of the rows, the gate electrode of the thin-film transistor operating as a switching element included in the pixel circuit 31. The source line 60 is connected to, for each of the columns, the source electrode of the thin-film transistor operating as the switching element included in the pixel circuit 31. The power source line is connected to, for each of the columns, the drain electrode of the thin-film transistor operating as a drive element included in the pixel circuit 31.

Next, a circuit configuration of the pixel circuit 31 of the pixel 30 is described, with reference to FIG. 2. FIG. 2 is an electric circuit diagram showing a simplified configuration of the pixel circuit included in the organic EL display apparatus according to Embodiment.

As shown in FIG. 2, the pixel circuit 31 includes a thin-film transistor 32 operating as a drive element, a thin-film transistor 33 operating as a switching element, and a capacitor 34 storing data used for displaying on the corresponding pixel 30. In Embodiment, the thin-film transistor 32 is a drive transistor for driving the organic EL element 40, and the thin-film transistor 33 is a switching transistor for selecting the pixel 30.

The thin-film transistor 32 includes the following: a gate electrode 32g connected to a drain electrode 33d of the thin-film transistor 33 and to one terminal of the capacitor 34; a drain electrode 32d connected to a power source line 70; a source electrode 32s connected to the anode 41 of the organic EL element and to the other terminal of the capacitor 34; and a semiconductor film (not illustrated). The thin-film transistor 32 supplies a current corresponding to data voltage held by the capacitor 34 from the power source line 70 to the anode 41 of the organic EL element 40, via the source electrode 32s. This enables the organic EL element 40 to have a drive current flowing from the anode 41 to the cathode 43, thereby allowing the EL layer 42 to emit light.

The thin-film transistor 33 includes the following: a gate electrode 33g connected to the gate line 50; a source electrode 33s connected to the source line 60; a drain electrode 33d connected to one terminal of the capacitor 34 and to the gate electrode 32g of the thin-film transistor 32; and a semiconductor film (not illustrated). When a predetermined voltage is applied to the gate line 50 and the source line 60 both connected to the thin-film transistor 33, the voltage applied to the source line 60 is stored as data voltage into the capacitor 34.

It should be noted that the organic EL display apparatus 10 having the aforementioned configuration adopts the active matrix scheme by which display control is performed for each of the pixels 30 located at intersection points of the gate lines 50 and the source lines 60. With this, the thin-film transistors 32 and 33 of the individual pixel 30 (each of subpixels R, G, and B) selectively cause the corresponding organic EL element 40 to emit light. As a result, a desired image is displayed.

### [Thin-Film Transistor]

The following describes the thin-film transistor according to Embodiment. Note that the thin-film transistor according to Embodiment is a bottom-gate channel-protection (top-contact) thin-film transistor.

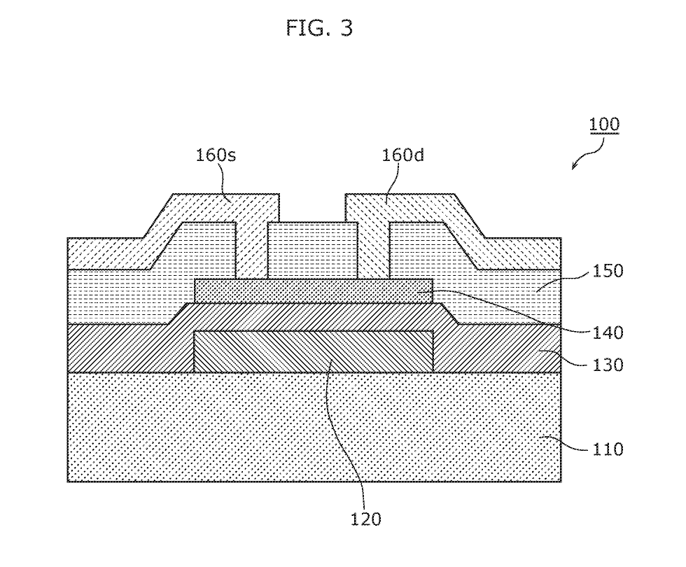

FIG. 3 is a schematic cross-sectional view of the thin-film transistor according to Embodiment.

As shown in FIG. 3, a thin-film transistor 100 according to Embodiment includes a substrate 110, a gate electrode 120, a gate insulating film 130, an oxide semiconductor layer 140, a channel protection layer 150, a source electrode 160s, and a drain electrode 160d.

The substrate 110 comprises an electrically insulating material. Examples of the material of the substrate 110 include the following: a glass material, such as alkali-free glass, silica glass, or high heat resistant glass; a resin material, such as polyethylene resin, polypropylene resin, or polyimide resin; a semiconductor material, such as silicon or gallium arsenide; or a metal material, such as stainless material coated with an insulating layer.

Note that the substrate 110 is not limited to a rigid substrate and may be a flexible substrate, such as a flexible resin substrate. In this case, the thin-film transistor 100 can be used as a TFT for a flexible display.

The gate electrode 120 is formed in a predetermined shape above the substrate 110. The gate electrode 120 comprises an electrically conductive material. Examples of the material of the gate electrode 120 includes the following: a metal, such as molybdenum, aluminum, copper, tungsten, titanium, manganese, chromium, tantalum, niobium, silver, gold, platinum, palladium, indium, nickel, or neodymium; a metal alloy comprising metals selected from among these metals; an electrically conductive metal oxide, such as indium tin oxide (ITO), aluminum-doped zinc oxide (AZO), or gallium-doped zinc oxide (GZO); or an electrically conductive polymer, such as polythiophene or polyacetylene. The gate electrode 120 may have a multilayer structure in which these materials are laminated. For example, the gate electrode 120 has a laminated structure in which a molybdenum (Mo) film and a copper (Cu) film are laminated, and has a film thickness of 20 nm to 500 nm.

The gate insulating film (gate insulating layer) 130 is formed on the gate electrode 120. For example, the gate insulating film 130 is formed on both the gate electrode 120 and the substrate 110 in a manner that the gate electrode 120 is covered. To be more specific, the gate insulating film 130 is formed on the substrate 110 to completely cover the gate electrode 120.

The gate insulating film 130 comprise an electrically insulating material. For example, the gate insulating film 130 is a single-layer film comprising one of, or a multilayer film comprising, a silicon oxide film, a silicon nitride film, a silicon oxynitride film, an aluminum oxide film, a tantalum oxide film, and a hafnium oxide film. As an example, the gate insulating film 130 has a laminated structure in which a silicon oxide film and a silicon nitride film are laminated, and has a film thickness of 50 nm to 300 nm.

The oxide semiconductor layer 140 is used as a channel layer of the thin-film transistor 100. To be more specific, the oxide semiconductor layer 140 is a semiconductor layer that includes a channel region. The semiconductor layer 140 and the gate electrode 120 are opposite to each other, with the gate insulating film 130 being interposed in between.

The oxide semiconductor layer 140 is formed in a predetermined shape on the gate insulating film. For example, the oxide semiconductor layer 140 is formed above the gate electrode 120. To be more specific, the oxide semiconductor layer 140 and the gate electrode 120 are opposite to each other, with the gate insulating film 130 interposed in between. As an example, the oxide semiconductor layer 140 is formed on the gate insulating film 130 and above the gate electrode 120, in the shape of an island.

The oxide semiconductor layer 140 comprises an oxide semiconductor material containing at least one of indium (In), gallium (Ga), and zinc (Zn). For example, the oxide semiconductor layer 140 comprises a transparent amorphous oxide semiconductor (TAOS) such as amorphous indium gallium zinc oxide (InGaZnO: IGZO). The oxide semiconductor layer 140 has a film thickness of 20 nm to 200 nm, as an example. The oxide semiconductor layer 140 has a carrier density of, for example, between about 1.13×10¹³ cm⁻³ and about 1.13×10¹⁶ cm⁻³ inclusive.

The ratio among In, Ga, and Zn contained in the oxide semiconductor layer 140 is about 1:1:1, for example. Moreover, the range of the ratio among In, Ga, and Zn may be, but not limited to, 0.8 to 1.2:0.8 to 1.2:0.8 to 1.2.

The thin-film transistor having the channel layer comprising the transparent amorphous oxide semiconductor has a high carrier mobility and is thus suitable for a large-sized screen or a high-resolution display apparatus. Moreover, the transparent amorphous oxide semiconductor, which enables a low-temperature film formation, can be easily formed on a flexible substrate comprising, for example, plastic or film.

The channel protection layer 150 is an example of an insulating layer formed on the oxide semiconductor layer 140. On this account, the channel protection layer 150 comprises an electrically insulating material. For example, the channel protection layer 150 is a single-layer film comprising one of, or a multilayer film comprising, the following: a film comprising an inorganic material, such as a silicon oxide film, a silicon nitride film, a silicon oxynitride film, or an aluminum oxide film; and a film comprising an inorganic material containing silicon, oxygen, and carbon. The channel protection layer 150 has a film thickness of 50 nm to 500 nm, as an example.

Moreover, the channel protection layer 150 functions as an etch stopper layer. The etch stopper layer prevents the oxide semiconductor layer 140 from being etched when the source electrode 160s and the drain electrode 160d to be formed above the oxide semiconductor layer 140 are patterned by etching.

The channel protection layer 150 has a through opening. In other words, the channel protection layer 150 has a contact hole to partially expose the oxide semiconductor layer 140.

The oxide semiconductor layer 140 is connected to the source electrode 160s and the drain electrode 160d via the through opening (the contact hole) of the channel protection layer 150. The size of the contact hole in the channel width direction of the oxide semiconductor layer 140 (i.e., the size of the width) is smaller than the width of the oxide semiconductor layer 140 by 10 μm or more, for example.

Each of the source electrode 160s and the drain electrode 160d is located at least partially above the channel protection layer 150, and is connected to the oxide semiconductor layer 140 via the opening formed in the channel protection layer 150. In other words, each of the source electrode 160s and the drain electrode 160d is formed above the channel protection layer 150 to be connected to the part of the oxide semiconductor layer 140 which is exposed by means of the channel protection layer 150. To be more specific, the source electrode 160s and the drain electrode 160d are connected to the oxide semiconductor layer 140 via the contact hole formed in the channel protection layer 150, and separately disposed opposite to each other on the channel protection layer 150 in the horizontal direction of the substrate.

Each of the source electrode 160s and the drain electrode 160d comprises an electrically conductive material. For the materials of the source electrode 160s and the drain electrode 160d, the same material as the material of the gate electrode 120 can be used as an example. Each of the source electrode 160s and the drain electrode 160d has a laminated structure in which a Mo film, a Cu film, and a CuMn film are laminated, and has a film thickness of 100 nm to 500 nm.

### [Method of Manufacturing Thin-Film Transistor]

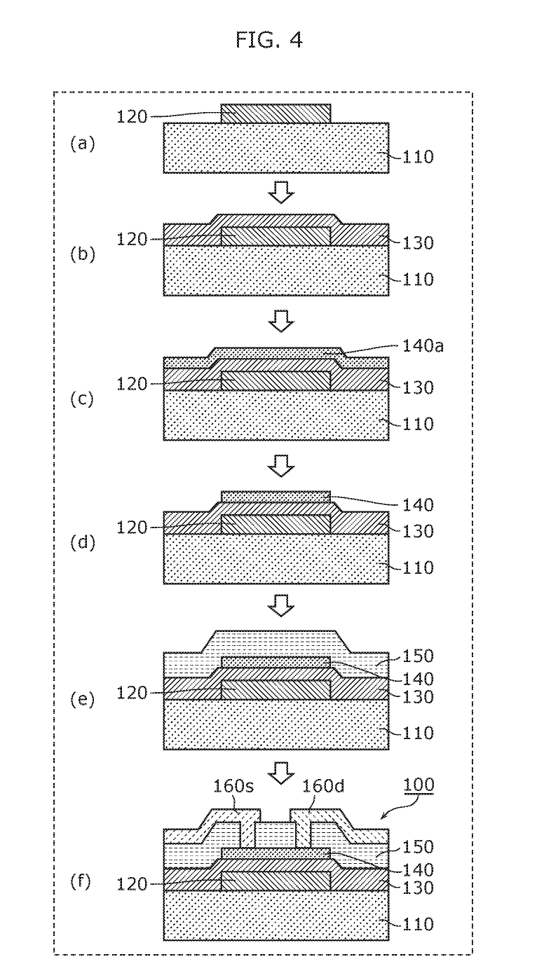

Next, a method of manufacturing the thin-film transistor according to Embodiment is described, with reference to FIG. 4. FIG. 4 is a schematic cross-sectional view showing the method of manufacturing the thin-film transistor according to Embodiment.

First, the substrate 110 is prepared, and the gate electrode 120 is formed in a predetermined shape above the substrate 110 as shown in (a) of FIG. 4. The gate electrode 120 is formed in the predetermined shape by, for example, forming a metal film on the substrate 110 by a sputtering method and subsequently processing this metal film by a photolithography method and a wet etching method. Note that wet etching can be performed on the metal film using, for example, a chemical solution mixture of hydrogen peroxide solution (H₂O₂) and organic acid.

Next, the gate insulating film 130 is formed on the gate electrode 120, as shown in (b) of FIG. 4. The gate insulating film 130 is formed by, for example, forming a silicon nitride film and a silicon oxide film in this order on both the gate electrode 120 and the substrate 110 by a plasma chemical vaper deposition (CVD) method in a manner that the gate electrode 120 is covered.

The silicon nitride film can be formed using, for example, silane gas (SiH₄), ammonia gas (NH₃), or nitrogen gas (N₂) as an introduced gas. As an example, the silicon nitride film is formed using ammonia gas (NH₃) at a temperature of 400° C. The silicon oxide film can be formed using, for example, silane gas (SiH₄) and nitrous oxide gas (N₂O) as an introduced gas.

Next, an oxide semiconductor film 140a is formed above the substrate 110, as shown in (c) of FIG. 4. The oxide semiconductor film 140a is formed on the gate insulating film 130 by, for example, the sputtering method. The oxide semiconductor film 140a has a film thickness of between about 20 nm and about 200 nm inclusive, for example.

To be more specific, an amorphous InGaZnO film comprising a target material having the composition ratio In:Ga:Zn=1:1:1 is formed on the entire surface of the gate insulating film 130 in an oxygen atmosphere by the sputtering method. The oxide semiconductor layer 140 has a carrier density of, for example, between about 1.13×10¹³ cm⁻³ and about 1.13×10¹⁶ cm⁻³ inclusive.

Next, the oxide semiconductor layer 140 is formed by forming the oxide semiconductor film 140a into a predetermined shape as shown in (d) of FIG. 4. In other words, the oxide semiconductor layer 140 is formed by patterning the oxide semiconductor film 140a. For example, a resist in a predetermined shape is firstly formed on the oxide semiconductor film 140a. To be more specific, the resist is formed on the oxide semiconductor film 140a at a position opposite to the gate electrode 120, by the photolithography method,

Then, a region in which the resist is not formed on the oxide semiconductor film 140a is removed by the wet etching method. As a result of this process, the oxide semiconductor layer 140 is formed at the position opposite to the gate electrode 120. When the oxide semiconductor film 140a is, for example, an IGZO film, this etching process can be performed using, for example, a chemical solution mixture of phosphoric acid (H₃PO₄), nitric acid (HNO₃), acetic acid (CH₃COOH), and water.

Next, an insulating layer is formed on the oxide semiconductor layer 140 to partially expose the oxide semiconductor layer 140.

More specifically, the channel protection layer 150 is firstly formed on the oxide semiconductor layer 140, as shown in (e) of FIG. 4. For example, the channel protection layer 150 is formed on both the oxide semiconductor layer 140 and the gate insulating film 130 in a manner that the oxide semiconductor layer 140 is covered.

For example, the channel protection layer 150 can be formed by forming a silicon oxide film on both the oxide semiconductor layer 140 and the gate insulating film 130 by the plasma CVD method.

After this, the channel protection layer 150 is patterned into a predetermined shape. More specifically, a contact hole is formed in the channel protection layer 150 to partially expose the oxide semiconductor layer 140.

To be more precise, a contact hole is formed on a region that is to be a source contact region and a drain contact region of the oxide semiconductor layer 140, by partially etching the channel protection layer 150 by the photolithography method and a dry etching method. When the channel protection layer 150 is, for example, a silicon oxide film, a reactive ion etching (RIE) method can be used as the dry etching method. In this case, for example, carbon tetrafluoride (CF₄) and oxygen gas (O₂) can be used as an etching gas. Parameters of, for example, a gas flow rate, a pressure, electric power to be applied, and a frequency are appropriately set in accordance with the size of the substrate, the thickness of the film to be etched, and so forth.

The size of the contact hole in the channel width direction of the oxide semiconductor layer 140 (i.e., the size of the width) is smaller than the width of the oxide semiconductor layer 140 by about 10 μm or more, for example. Moreover, a protrusion width of the oxide semiconductor layer 140 on the source electrode 160s side or a protrusion width of the oxide semiconductor layer 140 on the drain electrode 160d side is about 5 μm or more, for example.

Next, the source electrode 160s and the drain electrode 160d both of which are to be connected to the oxide semiconductor layer 140 are formed, as shown in (f) of FIG. 4. For example, the source electrode 160s and the drain electrode 160d in predetermined shapes are formed on the channel protection layer 150 in a manner that the contact hole formed in the channel protection layer 150 is filled.

More specifically, the source electrode 160s and the drain electrode 160d are formed, spaced from each other, on the channel protection layer 150 and in the contact hole. To be more precise, a Mo film, a Cu film, and a CuMn film are formed in this order on the channel protection layer 150 and in the contact hole, by the sputtering method. Then, the Mo film, the Cu film, and the CuMn film are patterned by the photolithography method and the wet etching method to form the source electrode 160s and the drain electrode 160d.

Each of the source electrode 160s and the drain electrode 160d has a film thickness of between about 100 nm and about 500 nm inclusive, for example. The wet etching can be performed on the Mo film, the Cu film, and the CuMn film using, for example, a chemical solution mixture of hydrogen peroxide solution (H₂O₂) and organic acid. One of, or both, the width of the source electrode 160s and the width of the drain electrode 160d is, or are, smaller than the width of the oxide semiconductor layer 140, according to Embodiment.

As described thus far, the thin-film transistor can be manufactured.

### [Protrusion Width of Oxide Semiconductor Layer]

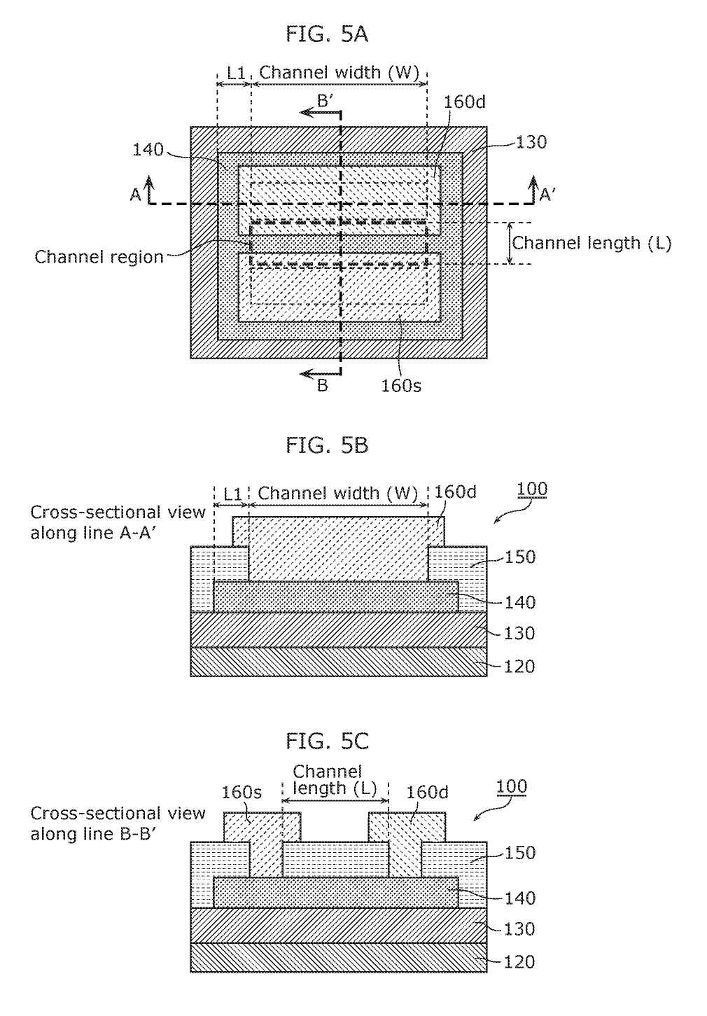

The following describes a relationship between a protrusion width L1 and an amount of shift in a threshold voltage in the thin-film transistor 100 that has the oxide semiconductor layer 140 protruding both from the source electrode 160s and from the drain electrode 160d by the protrusion width L1 (μm), with reference to FIG. 5A to FIG. 5C.

FIG. 5A is a plan view of the thin-film transistor 100 seen from above. FIG. 5B is a cross-sectional view of the thin-film transistor 100 taken along a line A-A′ of FIG. 5A. FIG. 5C is a cross-sectional view of the thin-film transistor 100 taken along a line B-B′ of FIG. 5A.

As shown in FIG. 5A to FIG. 5C, the protrusion width L1 (μm) of the oxide semiconductor layer 140 in the channel width direction is defined as a length from an edge part of the oxide semiconductor layer 140 in the channel width direction to a line where the drain electrode 160d (or the source electrode 160s) meets the oxide semiconductor layer 140.

Note that the channel region (the inside channel region) of the oxide semiconductor layer 140 is indicated as a rectangle drawn by a thick broken line in FIG. 5A. More specifically, the channel region of the oxide semiconductor layer 140 is located between the source electrode 160s and the drain electrode 160d. To be more precise, the channel region is located between a part where the source electrode 160s meets the oxide semiconductor layer 140 and a part where the drain electrode 160d meets the oxide semiconductor layer 140. Note also that an outside channel region refers to a region other than the channel region, that is, a region outside the channel region.

### [Relationship Between Protrusion Width and Current Density Concentration]

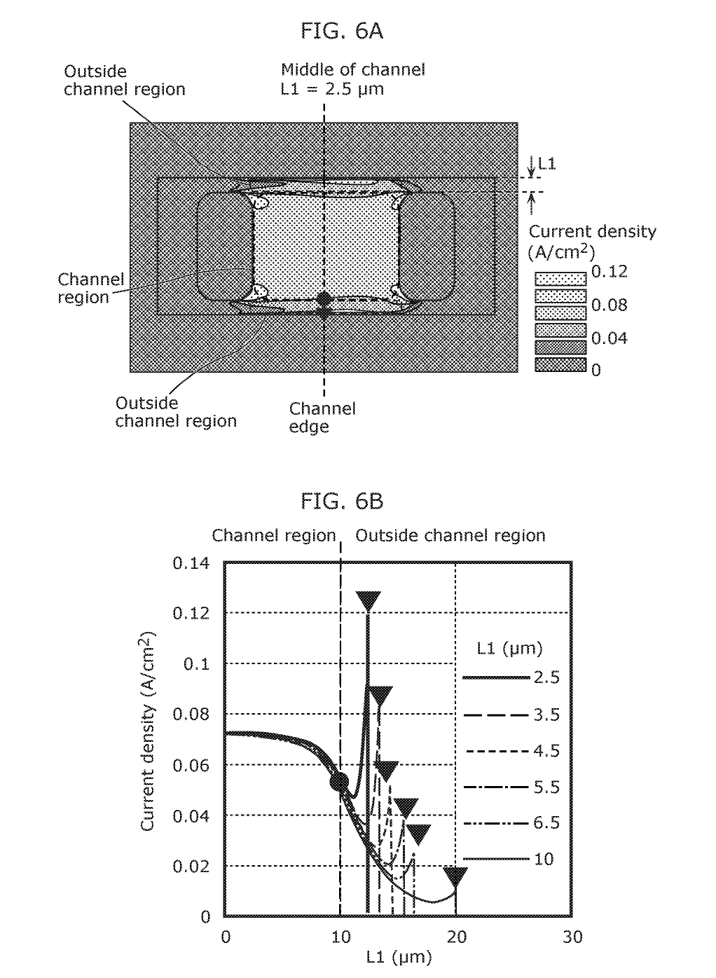

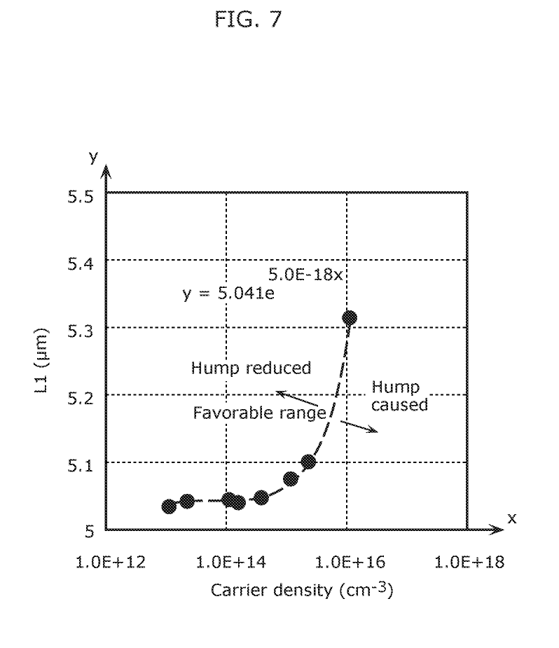

The following describes current density concentration caused to an edge part of the oxide semiconductor layer when the protrusion width L1 (μm) of the oxide semiconductor layer 140 and the carrier density (cm⁻³) of the oxide semiconductor layer 140 are controlled, with reference to FIG. 6A, FIG. 6B, and FIG. 7. Here, the current density concentration is calculated using device simulation software (product name: ATLAS).

FIG. 6A is a diagram showing current density distribution of the oxide semiconductor layer (when seen from above) of the thin-film transistor when a drain voltage is applied, according to Embodiment. The density distribution shown in FIG. 6A is a current density distribution in the oxide semiconductor layer 140 when a voltage of 4 V is applied to the drain electrode while the source electrode is at ground potential.

In FIG. 6A, the oxide semiconductor layer is located on the gate insulating film, and the source electrode and the drain electrode are disposed opposite to each other with a 20-μm spacing in between. Moreover, the source electrode and the drain electrode are processed to have the corners of the edge parts with a curvature, which is reproduced as curvature=0.5.

As can be understood from FIG. 6A, a high current density occurs in the outside channel region. More specifically, a current path different from a main TFT is formed in the outside channel region to cause a sub-TFT, which results in the hump phenomenon.

FIG. 6B is a two-dimensional diagram of the current density distribution, shown in FIG. 6A, taken along the middle line of the channel in a Y direction. In FIG. 6B, (black circle) indicates the current density at the edge part of the channel region, and ▾ (black triangle) indicates the current density at the edge part of the oxide semiconductor layer.

As shown in FIG. 6B, when the protrusion width L1 (μm) is small, a high current density is caused locally at the edge part of the oxide semiconductor layer in the outside channel region.

In this way, the inventors have found that a high current density region equivalent to the inside channel region is caused at the edge part of the oxide semiconductor layer when the protrusion width L1 of the oxide semiconductor layer is not sufficiently large.

This high current density region is assumed to become a sub-TFT when the current density is higher than the current density of the inside channel region () and thereby cause the hump phenomenon. The hump phenomenon is thought to be reduced when the current density obtained by subtracting the current density at the point from the current density at the ▾ point is 0 (current density at ▾—the current density at =0) or less. Moreover, it can be understood that when the protrusion width L1 is larger, the current density in the outside channel region is smaller.

Such a distribution of the current density is thought to be caused not only by the protrusion width L1 (μm) but also by the carrier density of the oxide semiconductor layer. Here, conditions under which a value obtained by subtracting the current density at the point from the current density at the ▾ point is 0 or less are searched for by varying the carrier density and the protrusion width L1 (μm), and are plotted as shown in FIG. 7, FIG. 7 is a graph showing the relationship between the protrusion width L1 and the carrier density of the oxide semiconductor layer of the thin-film transistor.

As shown in FIG. 7, the relationship between the protrusion width L1 (μm) and the carrier density N (cm⁻³) is represented by the following relational expression (Expression 1) by approximating the points plotted under the aforementioned conditions.

L1=5.041 exp(5×10⁻¹⁸N) (Expression 1)

The localized concentration of the current density is thought to be reduced to eliminate the hump phenomenon in the region satisfying L1≧5,041 exp(5×10⁻¹⁸N), where a line satisfying Expression 1 is the boundary line. The satisfaction of L1≧5.041 exp(5×10⁻¹⁸N) stabilizes the initial characteristics of the thin-film transistor and increases the reliability of the NBTS (Negative Bias Temperature Stress) test. Note that, from L1≧5.041 exp(5×10⁻¹⁸N), a relational expression of the carrier density N can be derived as N≦2×10¹⁷ In(L1)−3.24×10¹⁷.

### EXAMPLE

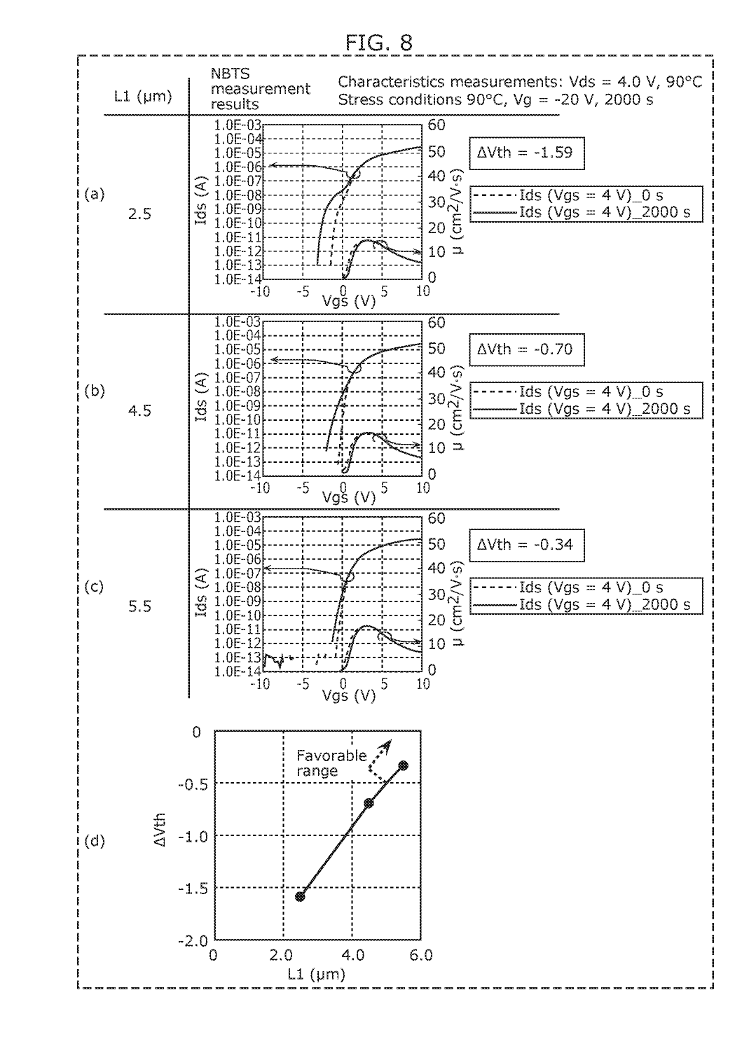

In FIG. 8, (a) to (c) show the relationships between the current and the gate voltage and between the carrier mobility and the gate voltage, as a result of the NBTS test performed on the thin-film transistor according to Embodiment. To be more specific, the NBTS test was performed on the thin-film transistors 100 different in the protrusion width L1 (μm) of the oxide semiconductor layer 140, the width varying from 2.5 μm to 5.5 μm in the channel width direction. Here, the NBTS test is a stress application test in which a negative bias is applied to the gate electrode.

Moreover, in (d) of FIG. 8, an amount of shift (an amount of change) ΔVth (V) of a threshold voltage Vth (V) in the NBTS test is plotted with respect to the respective protrusion widths L1 (μm) in (a) to (c) of FIG. 8.

Note that the NBTS test was performed under the stress conditions as follows: a gate-source voltage V_{gs}=−20 V; a drain-source voltage V_{ds}=0 V; a temperature T=90° C.; and a period of time t=2000 seconds. The amount of shift ΔVth (V) of the threshold voltage Vth refers to a difference (the amount of change) between a threshold voltage before the application of stress (the initial characteristics) and a threshold voltage after the application of stress. The thin-film transistor subjected to the NBTS test has a channel width (W) of 20 82 m and a channel length (L) of 11 μm. In (a) to (c) of FIG. 8, the initial characteristics (0 s) are indicated by a dotted line, and the characteristics after the application of stress (2000 s) are indicated by a solid line. Moreover, the left-side axis represents a drain-source current Ids (A), and the right-side axis represents a mobility μ (cm²/ V·s).

As shown in (a) and (b) of FIG. 8, the hump phenomenon is caused to a subthreshold region even when the oxide semiconductor layer 140 of the thin-film transistor has the protrusion width L1. In addition, the hump phenomenon is more apparent after the NBTS test.

On the other hand, as shown in (c) of FIG. 8, the hump phenomenon is not caused to the thin-film transistor having a large width as the protrusion width L1, even in the initial characteristics and even after the NBTS test. In addition, the amount of shift ΔVth (V) of the threshold voltage Vth caused by the NBTS test is also reduced.

Therefore, the hump phenomenon in (a) and (b) of FIG. 8 is thought to result from a current path that is different from the main TFT and caused by the locally high current density due to the irregular current density distribution at the edge part of the oxide semiconductor layer because the protrusion width L1 (μm) is small.

The edge part of the oxide semiconductor layer having damage or tapered edges caused by etching is apparent in degradation in the NBTS test. On this account, when the protrusion width L1 is small, the hump phenomenon is apparent after the NBTS test. It should be noted that when the protrusion width L1 is smaller, this influence is greater and thus reduce the reliability of the thin-film transistor.

On the other hand, no hump phenomenon in (c) of FIG. 8 is thought to result from the reduced current density in the outside channel region in the channel width (W) direction due to the regular current density distribution at the edge part of the oxide semiconductor layer because the protrusion width L1 (μm) is large. In other words, concentration of the current density, which may cause the hump phenomenon, did not occur. It should be noted that when the protrusion width L1 (μm) is larger, the current density in the outside channel region is reduced more in the channel width (W) direction.

Note that, in (a) and (b) of FIG. 8, the oxide semiconductor layer 140 has the carrier density N of, for example, between about 1.13×10¹³ cm⁻³ and about 1.13×10¹⁶ cm⁻³ inclusive.

It can be understood from the experimental results that the protrusion width L1 (μm) of the oxide semiconductor layer 140 should be controlled to reduce the hump phenomenon and increase the reliability of the NBTS test. As shown in (d) of FIG. 8, for example, the thin-film transistor having no hump phenomenon in the initial characteristics but having the increased reliability of the NBTS test can be obtained by setting the protrusion width L1 of the oxide semiconductor layer 140 in the channel width direction to be 5 μm or more.

### [Conclusion]

As described thus far, according to the thin-film transistor 100 and the method of manufacturing the same according to Embodiment, the protrusion width L1 (μm) of the oxide semiconductor layer 140 in the channel width direction with respect to the source electrode 160s or the drain electrode 160d and the carrier density N (cm⁻³) of the oxide semiconductor layer 140 satisfy the relational expression L1≧5.041 exp(5×10⁻¹⁸N).

The satisfaction of the relational expression allows the width of the oxide semiconductor layer 140 to be greater than the width of the source electrode 160s or the drain electrode 160d. Thus, the tapered parts of the edge parts of the oxide semiconductor layer 140 can be located outside the channel region. With this, the edge parts of the oxide semiconductor layer 140 can be distanced from the channel region, which state can suppress an occurrence of a region having a high current density at the edge parts of the oxide semiconductor layer 140.

As a consequence, the hump phenomenon in the initial characteristics of the thin-film transistor 100 is reduced and thereby the amount of negative shift of the threshold voltage is reduced. Hence, the thin-film transistor having more superior characteristics and higher reliability can be obtained.

### Other Embodiments

A technique disclosed in the present application has been described according to Embodiment as an example. However, the technique according to the present disclosure is not limited to this example, and is applicable to embodiments in which modifications, replacement, addition, or omissions are performed as appropriate.

In Embodiment above, the thin-film transistor is described as a bottom-gate channel-protection TFT as an example. However, the thin-film transistor is not limited to this type of TFT. For example, the thin-film transistor may be a bottom-gate channel-etched thin-film transistor or a top-gate TFT. To be more specific, the thin-film transistor includes the following: a gate electrode formed above a substrate; an oxide semiconductor layer formed opposite to the gate electrode; a gate insulating film formed between the gate electrode and the oxide semiconductor layer; and a source electrode and a drain electrode both connected to a part of the oxide semiconductor layer. Here, the width of the oxide semiconductor layer only has to be greater than the width of the source electrode and the width of the drain electrode.

Moreover, in Embodiment above, the oxide semiconductor material used for the oxide semiconductor layer is not limited to amorphous InGaZnO. For example, as an oxide semiconductor material having a crystalline structure, a polycrystalline semiconductor, a microcrystalline semiconductor, or a single-crystal semiconductor may be used. Moreover, as an oxide semiconductor material, InGaSnO, InGaO, InZnO, InSnO, or ZnO may be used for example.

Furthermore, in Embodiment above, the organic EL display apparatus has been described as the display apparatus including the thin-film transistor. However, the thin-film transistor according to Embodiment is applicable to different display apparatuses, such as liquid crystal display apparatuses, which include active matrix substrates.

Moreover, the display apparatus (the display panel) such as the aforementioned organic EL display apparatus can be used as a flat panel display. The display apparatus is also applicable to various kinds of electronic equipment having display panels, such as television sets, personal computers, or cellular phones. The display apparatus is particularly suitable for large-sized screens or high-resolution display apparatuses.

Other embodiments implemented through various changes and modifications conceived by a person of ordinary skill in the art or through a combination of the structural elements in different embodiments described above may be included in the scope in an aspect or aspects according to the present invention, unless such changes, modifications, and combination depart from the scope of the present invention.

### INDUSTRIAL APPLICABILITY

A thin-film transistor and a method of manufacturing the thin-film transistor according to the present disclosure can be used in, for example, display apparatuses such as organic EL display apparatuses.

### REFERENCE SIGNS LIST

10 Organic EL display apparatus

20 TFT substrate

30 Pixel

31 Pixel circuit

32, 33, 100 Thin-film transistor

32d, 33d, 160d Drain electrode

32g, 33g, 120 Gate electrode

32s, 33s, 160s Source electrode

34 Capacitor

40 Organic EL element

41 Anode

42 EL layer

43 Cathode

50 Gwate line

60 Source line

70 Power source line

110 Substrate

130 Gate insulating film

140 Oxide semiconductor layer

140a Oxide semiconductor film

150 Channel protection layer

1. A thin-film transistor comprising:
a gate electrode located above a substrate;
a gate insulating film located above the gate electrode;
an oxide semiconductor layer opposite to the gate electrode, with the gate insulating film being interposed in between;
an insulating layer formed above the oxide semiconductor layer; and
a source electrode and a drain electrode which are located at least partially above the insulating layer and are connected to the oxide semiconductor layer via an opening formed in the insulating layer,
wherein the thin-film transistor satisfies a relational expression L1≧5.041 exp(5×10⁻¹⁸N), where L1 (μm) is one of protrusion widths of the oxide semiconductor layer in a channel width direction with respect to one of the source electrode and the drain electrode and N (cm⁻³)is a carrier density of the oxide semiconductor layer.

2. The thin-film transistor according to claim 1,
wherein the carrier density N (cm⁻³) of the oxide semiconductor layer further satisfies a relational expression 1.13×10¹³ cm⁻³≦N≦1.13×10¹⁶ cm⁻³.

3. The thin-film transistor according to claim 1,
wherein the oxide semiconductor layer comprises a transparent amorphous oxide semiconductor.

4. The thin-film transistor according to claim 3,
wherein the oxide semiconductor layer comprises indium gallium zinc oxide (InGaZnO).

5. An organic electroluminescent (EL) display apparatus comprising the thin-film transistor according to claim 1.

6. A method of manufacturing a thin-film transistor having an oxide semiconductor layer, the method comprising:
forming a gate electrode above a substrate;
forming a gate insulating film above the gate electrode;
forming an oxide semiconductor film above the gate insulating film;
forming an oxide semiconductor layer by processing the oxide semiconductor film into a predetermined shape;
forming an insulating layer above the oxide semiconductor layer in a manner that causes the oxide semiconductor layer to have an exposed part; and
forming a source electrode and a drain electrode above the insulating layer in a manner that causes the source electrode and the drain electrode to be connected to the exposed part of the oxide semiconductor layer,
wherein the thin-film transistor satisfies a relational expression L1≧5.041 exp(5×10⁻¹⁸N), where L1 (μm) is one of protrusion widths of the oxide semiconductor layer in a channel width direction with respect to one of the source electrode and the drain electrode and N (cm⁻³) is a carrier density of the oxide semiconductor layer.

7. The method of manufacturing a thin-film transistor according to claim 6,
wherein the carrier density N (cm⁻³) of the oxide semiconductor layer further satisfies a relational expression 1.13×10¹³ cm⁻³≦N≦1.13×10¹⁶ cm⁻³.

8. The method of manufacturing a thin-film transistor according to claim 6,
wherein the oxide semiconductor film comprises a transparent amorphous oxide semiconductor.

9. The method of manufacturing a thin-film transistor according to claim 8,
wherein the oxide semiconductor film is an InGaZnO film.
